(19) United States
(12) Patent Application Publication
(10) Pub. No.: US 2026/0215325 A1
(43) Pub. Date: Jul. 23, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Sanghyeon Lee, Suwon-si (KR); Wonil Seo, Suwon-si (KR); Yonghyun Kim, Suwon-si (KR); Taejun Jeon, Suwon-si (KR); Hyunho Chu, Suwon-si (KR)

(21) Appl. No.: 19/350,508

(22) Filed: Oct. 6, 2025

(30) Foreign Application Priority Data
Jan. 22, 2025 (KR) 10-2025-0009825

(51) Int. Cl. H01L 23/00; H01L 23/28; H01L 23/498; H01L 25/065

(52) U.S. Cl. CPC H10W 74/00; H10W 90/00; H10W 90/701; H10W 72/523; H10W 72/552; H10W 72/5522; H10W 72/5525; H10W 72/553; H10W 72/555; H10W 90/732; H10W 90/754

(57) ABSTRACT

A semiconductor package has a wire bonding structure in which short circuits between wires are prevented and signal integrity (SI) characteristics are improved. The semiconductor package includes a package substrate, a chip stack structure mounted on the package substrate and including at least two semiconductor chips, a bonding wire connecting each of the at least two semiconductor chips to the package substrate, and a sealing material sealing the chip stack structure and the bonding wire on the package substrate. The bonding wire includes a metal wire and a coating layer covering the metal wire and including at least one layer.

### CROSS-REFERENCE TO RELATED APPLICATION

This application is based on and claims priority under 35 U.S.C. § 119 to Korean Patent Application No. 10-2025-0009825, filed on Jan. 22, 2025, in the Korean Intellectual Property Office, the disclosure of which is incorporated by reference herein in its entirety.

### BACKGROUND

With the rapid development of the electronics industry and increasing user demands, electronic devices are becoming increasingly smaller and lighter. As electronic devices become smaller and lighter, semiconductor packages used in electronic devices are also being miniaturized and made lighter. Moreover, semiconductor packages are required to have high reliability in addition to high performance and large capacity. For example, as semiconductor packages become smaller and operate at high speeds, signal integrity (SI) characteristics may deteriorate due to noise, which may lead to reliability issues in semiconductor packages. Therefore, research and development have been continuously conducted on package structures to address the deterioration in SI characteristics.

### SUMMARY

The present disclosure provides a semiconductor package having a wire bonding structure in which short circuits between wires are prevented and signal integrity (SI) characteristics are improved. The present disclosure also provides a method of manufacturing the semiconductor package.

Implementations of the present disclosure are not limited to the aforesaid, and other implementations not described above will be clearly understood by those skilled in the art from descriptions below.

According to some implementations of the present disclosure, there is provided a semiconductor package. The semiconductor package includes a package substrate, a chip stack structure mounted on the package substrate and including at least two semiconductor chips, a bonding wire connecting each of the at least two semiconductor chips to the package substrate, and a sealing material sealing the chip stack structure and the bonding wire on the package substrate, wherein the bonding wire includes a metal wire and a coating layer covering the metal wire and including at least one layer.

According to some implementations of the present disclosure, there is provided a semiconductor package. The semiconductor package includes a package substrate including a substrate pad, a chip stack structure mounted on the package substrate and including at least two semiconductor chips, a metal wire connecting a chip pad of each of the at least two semiconductor chips and the substrate pad to each other, a coating layer covering the package substrate, the chip stack structure, and the metal wire, and including at least one insulating layer, and a sealing material sealing the chip stack structure and the metal wire on the package substrate.

According to some implementations of the present disclosure, there is provided a semiconductor package. The semiconductor package includes a package substrate, a chip stack structure mounted on the package substrate and including at least two semiconductor chips, a metal wire connecting each of the at least two semiconductor chips to the package substrate, a coating layer covering the package substrate, the chip stack structure, and the metal wire, and including a first insulating layer and a second insulating layer, and a sealing material sealing the chip stack structure and the metal wire on the package substrate.

### BRIEF DESCRIPTION OF THE DRAWINGS

Implementations will be more clearly understood from the following detailed description taken in conjunction with the accompanying drawings in which:

FIG. 1 is a cross-sectional view illustrating a semiconductor package according to an implementation.

FIGS. 2A to 2C are enlarged views illustrating portions A1, B1, and C1 of FIG. 1.

FIG. 3 is a cross-sectional view illustrating a semiconductor package according to an implementation.

FIGS. 4A, 4B, and 4C are enlarged views illustrating portions A2, B2, and C2 of FIG. 3.

FIGS. 5A and 5B are cross-sectional views illustrating semiconductor packages according to implementations.

FIGS. 6A, 6B, and 6C are cross-sectional views illustrating semiconductor packages according to implementations.

FIGS. 7A, 7B, 7C, 7D, 7E, 7F, and 7G are cross-sectional views schematically illustrating processes in a method of manufacturing a semiconductor package, according to an implementation.

FIGS. 8A and 8B are cross-sectional views schematically illustrating processes in a method of manufacturing a semiconductor package, according to an implementation.

FIGS. 9A, 9B, 9C, and 9D are cross-sectional views schematically illustrating processes in a method of manufacturing a semiconductor package, according to an implementation.

FIGS. 10A, 10B, 10C, 10D, and 10E are plan views and cross-sectional views illustrating mask shapes in the process shown in FIG. 9A.

### DETAILED DESCRIPTION

Hereinafter, implementations will be described with reference to the accompanying drawings. In the drawings, like reference numerals denote like elements, and repeated descriptions thereof are omitted.

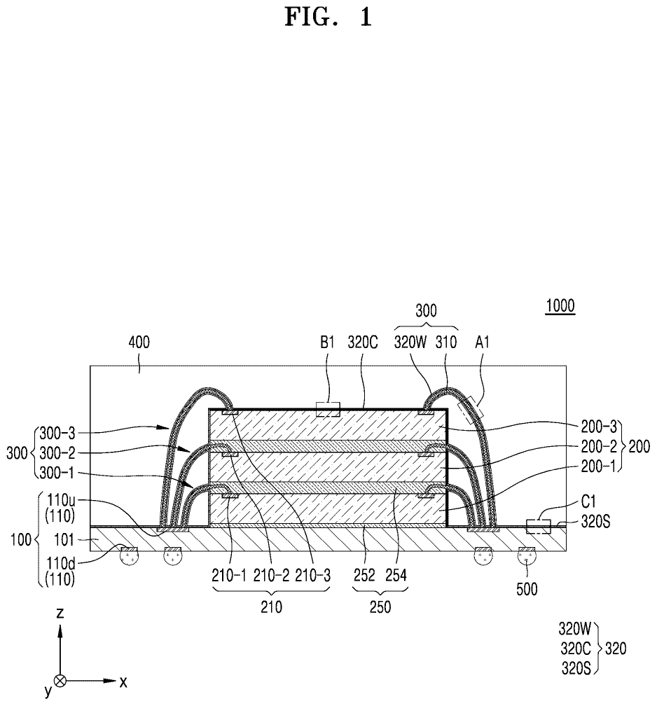

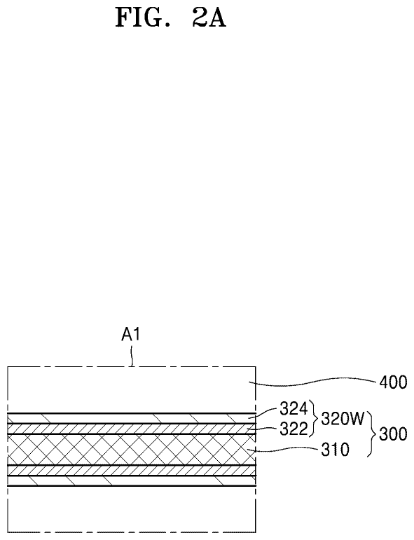

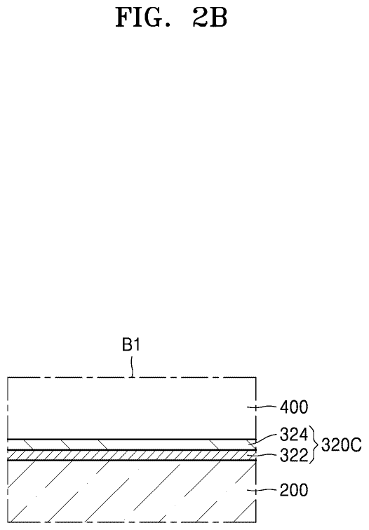

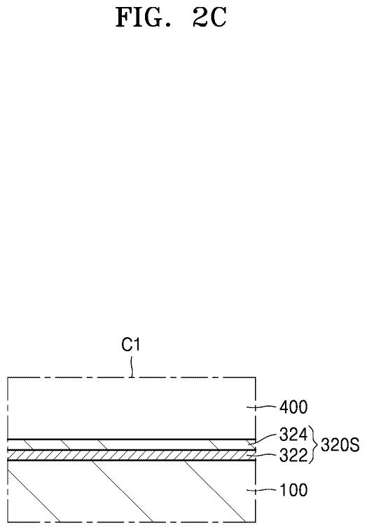

FIG. 1 is a cross-sectional view illustrating a semiconductor package 1000 according to an implementation, and FIGS. 2A to 2C are enlarged views illustrating portions A1, B1, and C1 of FIG. 1.

Referring to FIGS. 1 to 2C, the semiconductor package 1000 of some implementations may include a package substrate 100, a chip stack structure 200, bonding wires 300, a sealing material 400, and external connection terminals 500.

The package substrate 100 may be disposed under the chip stack structure 200 and may support the chip stack structure 200. The package substrate 100 may include, for example, a ceramic substrate, a printed circuit board (PCB), an organic substrate, or an interposer substrate. In some implementations, the package substrate 100 may include an active wafer such as a silicon wafer. In the semiconductor package 1000 of some implementations, the package substrate 100 may include a PCB. However, the package substrate 100 is not limited to a PCB.

The package substrate 100 may include a substrate body layer 101 and substrate pads 110. The substrate body layer 101 may form the body of the package substrate 100 and may include internal multiple wiring layers. For example, when the package substrate 100 is a PCB, the substrate body layer 101 may include a core layer and a wiring layer.

The core layer may include, for example, glass fiber such as FR4 and a resin. In addition, the core layer may include a build-up film such as a bismaleimide-triazine (BT) resin, a polycarbonate (PC) resin, an Ajinomoto build-up film (ABF), or a laminate resin. In some implementations, the core layer may be omitted.

The wiring layer may be distinguished based on the core layer into an upper wiring layer and a lower wiring layer. The upper and lower wiring layers may each include multilayered wires. The upper and lower wiring layers may have the same number of layers of wires or different numbers of layers of wires. In the semiconductor package 1000 of some implementations, the wiring layer of the package substrate 100 may include about eight to about twenty layers of wires. However, the number of layers of wires of the wiring layer is not limited to this numerical range.

The wiring layer may include multilayered wires, interlayer insulating layers that insulate the wires from each other, and vertical vias that connect the wires to each other. The wires and the vertical vias may include, for example, copper (Cu). However, the materials of the wires and the vertical vias are not limited to Cu. The interlayer insulating layers may include, for example, prepreg (PPG). The material of the interlayer insulating layers is not limited to PPG.

In some implementations, protective layers may be respectively provided on lower and upper surfaces of the substrate body layer 101. The protective layers may protect the substrate body layer 101 and the wiring layer from external physical and chemical agents. The protective layers may include, for example, solder resist (SR). However, the material of the protective layers is not limited to SR. For example, depending on the type or function of the package substrate 100, the protective layers may include passivation layers such as oxide layers or nitride layers. In addition, the substrate pads 110 provided on the upper and lower surfaces of the substrate body layer 101 may be exposed from the protective layers. In addition, the substrate body layer 101 may form the majority of the package substrate 100 and may be substantially identical in external shape to the package substrate 100. Therefore, the substrate body layer 101 and the package substrate 100 may be interchangeably referred to herein.

The substrate pads 110 may include upper substrate pads 110u on the upper surface of the substrate body layer 101, and lower substrate pads 110d on the lower surface of the substrate body layer 101. The upper substrate pads 110u may be exposed from the protective layer on the upper surface of the substrate body layer 101, and the lower substrate pads 110d may be exposed from the protective layer on the lower surface of the substrate body layer 101. The upper substrate pads 110u and the lower substrate pads 110d may be connected to the wires of the wiring layer.

The bonding wires 300 may be connected to the upper substrate pads 110u. For example, the upper substrate pads 110u may be electrically connected to each of semiconductor chips of the chip stack structure 200 through the bonding wires 300. In some implementations, the upper substrate pads 110u may be referred to as bonding pads. The external connection terminals 500 may be disposed on the lower substrate pads 110d. In some implementations, the substrate pads 110 may be included as portions of the wires of the wiring layer.

The chip stack structure 200 may include three semiconductor chips, that is, first to third semiconductor chips 200-1 to 200-3, stacked on the package substrate 100. In the semiconductor package 1000 of some implementations, the chip stack structure 200 may include three semiconductor chips, that is, the first to third semiconductor chips 200-1 to 200-3. However, the number of semiconductor chips of the chip stack structure 200 is not limited to three. For example, the chip stack structure 200 may include two or four or more semiconductor chips.

The chip stack structure 200 may include the first semiconductor chip 200-1, the second semiconductor chip 200-2, and the third semiconductor chip 200-3 that are sequentially stacked on the package substrate 100. The first semiconductor chip 200-1 may be attached and fixed to the package substrate 100 through an adhesive layer 250. In addition, each of the second semiconductor chip 200-2 and the third semiconductor chip 200-3 may be attached and fixed to a corresponding lower semiconductor chip through an adhesive layer 250.

The adhesive layers 250 may include a first adhesive layer 252 and second adhesive layers 254. The first adhesive layer 252 may be disposed between the first semiconductor chip 200-1 and the package substrate 100, and each of the second adhesive layers 254 may be disposed between two adjacent semiconductor chips. For example, the second adhesive layers 254 may be thicker than the first adhesive layer 252. As shown in FIG. 1, chip pads 210 may be disposed on an upper surface of each of the first to third semiconductor chips 200-1 to 200-3, and the bonding wires 300 may be connected to the chip pads 210. Therefore, the second adhesive layers 254 each provided between adjacent two semiconductor chips may have a sufficient thickness to allow bonding wires 300 to pass therethrough. In some implementations, the adhesive layers 250 may each include a die attach film (DAF). In some implementations, the first adhesive layer 252 and the second adhesive layers 254 may have substantially the same thickness.

The first semiconductor chip 200-1, the second semiconductor chip 200-2, and the third semiconductor chip 200-3 of the chip stack structure 200 may be identical in size and function. Therefore, hereinafter, the first semiconductor chip 200-1 will be mainly described.

The first semiconductor chip 200-1 may be disposed on the package substrate 100 with the adhesive layer 250 therebetween. The first semiconductor chip 200-1 may include a chip body and an active layer. The chip body may include, for example, a semiconductor element such as silicon (Si) or germanium (Ge). In addition, the chip body may include a compound semiconductor such as silicon carbide (SiC), gallium arsenide (GaAs), indium arsenide (InAs), or indium phosphide (InP). The chip body may have a silicon-on-insulator (SOI) structure. For example, the chip body may include a buried oxide (BOX) layer.

Structures such as a well doped with a dopant or a source/drain region doped with a dopant may be provided in an upper portion of the chip body as conductive regions, and the conductive regions may be part of the active layer. The chip body may include various isolation structures such as a shallow trench isolation (STI) structure.

The active layer may include an integrated circuit layer and multiple wiring layers on the integrated circuit layer. The integrated circuit layer may include various types of devices. For example, the integrated circuit layer may include various active and/or passive devices including: a field effect transistor (FET) such as a planar FET or a fin FET (FinFET); memory such as flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), or resistive random access memory (RRAM); a logic gate such as an AND, OR, or NOT gate; a system large-scale integration (LSI) device; a complementary metal-oxide-semiconductor (CMOS) image sensor (CIS); or a micro-electro-mechanical system (MEMS).

In the semiconductor package 1000 of some implementations, the first semiconductor chip 200-1 may be a memory chip. Therefore, the integrated circuit layer of the active layer of the first semiconductor chip 200-1 may include a plurality of memory devices. For example, the integrated circuit layer of the active layer of the first semiconductor chip 200-1 may include volatile memory devices such as DRAM and SRAM, or non-volatile memory devices such as PRAM, MRAM, FeRAM, or RRAM. For instance, in the semiconductor package 1000 of some implementations, the first semiconductor chip 200-1 may include DRAM devices in the integrated circuit layer of the active layer. Therefore, the first semiconductor chip 200-1 may be a DRAM chip. However, in the semiconductor package 1000 of some implementations, the type of the first semiconductor chip 200-1 is not limited to a DRAM chip. In addition, the type of the first semiconductor chip 200-1 is not limited to a memory chip.

The multiple wiring layers may be disposed on the integrated circuit layer. The multiple wiring layers may connect at least two devices to each other. In addition, the multiple wiring layers may connect devices to the conductive regions of the active layer or to the chip pads 210. The multiple wiring layers may include multilayered wires, and the multilayered wires in different layers may be connected to each other through vertical vias. Furthermore, the multilayered wires may be connected to the conductive regions through contacts.

The first semiconductor chip 200-1 may be mounted on the package substrate 100 by wire bonding. For example, first chip pads 210-1 of the first semiconductor chip 200-1 may be electrically connected to the upper substrate pads 110u of the package substrate 100 through first bonding wires 300-1. For example, when the first semiconductor chip 200-1 is mounted on the package substrate 100 by wire bonding, the active layer of the first semiconductor chip 200-1 may face upward. In other words, an upper surface of the first semiconductor chip 200-1, on which the active layer is formed, may be a front side of the first semiconductor chip 200-1, and a lower surface of the first semiconductor chip 200-1 may be a back side of the first semiconductor chip 200-1. The back side of the first semiconductor chip 200-1 may face the package substrate 100 and may be bonded to an upper surface of the package substrate 100 via the adhesive layer 250.

In addition, the second semiconductor chip 200-2 and the third semiconductor chip 200-3 may also be mounted above the package substrate 100 by wire bonding. For example, second chip pads 210-2 of the second semiconductor chip 200-2 may be electrically connected to the upper substrate pads 110u of the package substrate 100 through second bonding wires 300-2. In addition, third chip pads 210-3 of the third semiconductor chip 200-3 may be electrically connected to the upper substrate pads 110u of the package substrate 100 through third bonding wires 300-3.

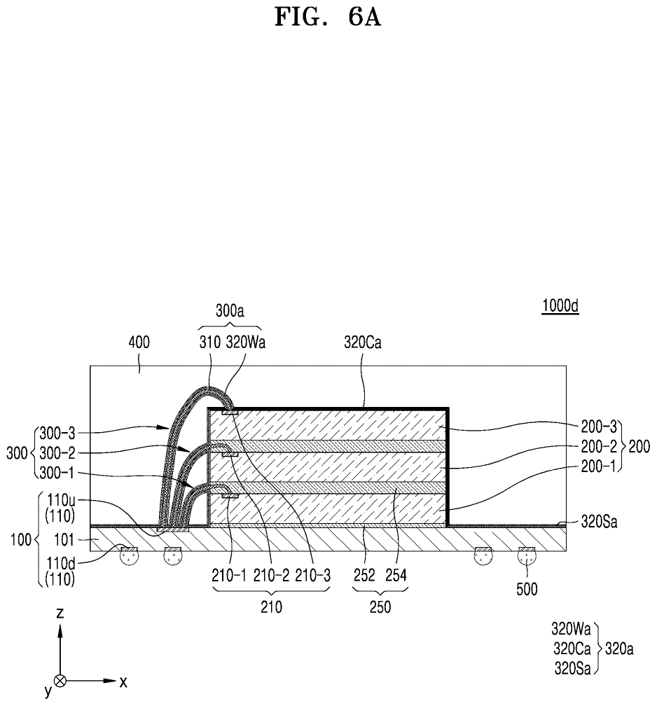

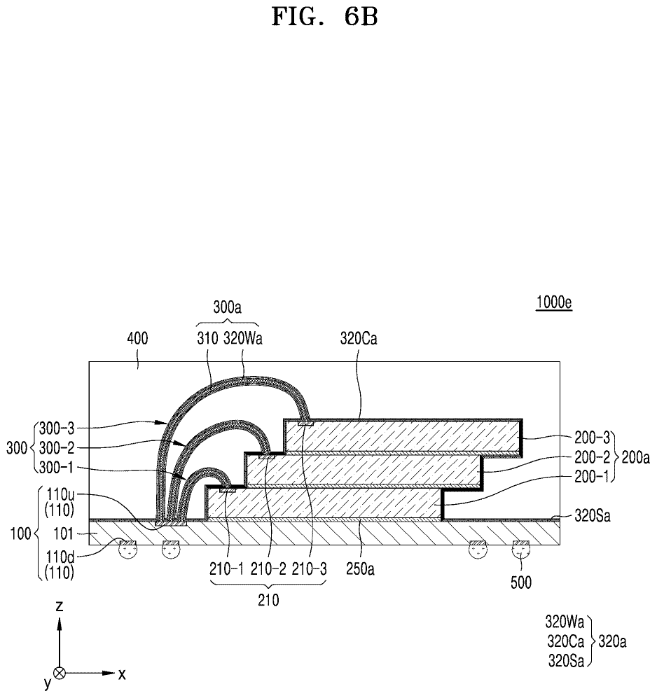

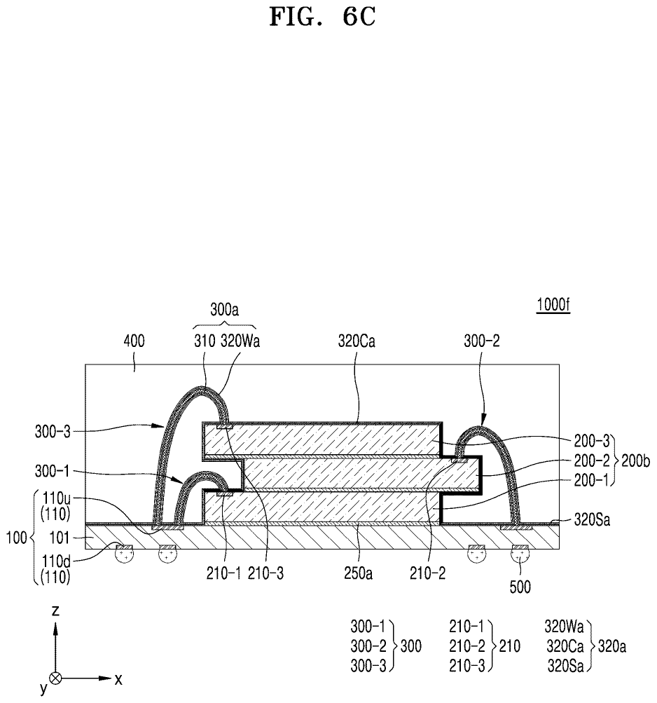

In the semiconductor package 1000 of some implementations, the chip stack structure 200 may have a vertical configuration in which lateral surfaces of the first to third semiconductor chips 200-1 to 200-3 are aligned in a vertical direction. That is, the lateral surfaces of the first to third semiconductor chips 200-1 to 200-3 may be aligned with each other in the vertical direction. However, the chip stack structure 200 is not limited to the vertical configuration in which lateral surfaces thereof are aligned. In the semiconductor package 1000 of some implementations, the bonding wires 300 may be arranged on both sides in a x-direction. However, the arrangement of the bonding wires 300 is not limited thereto. Other arrangements of the bonding wires 300 and various configurations of the chip stack structure 200 are described with reference to FIGS. 6A to 6C.

In the semiconductor package 1000 of some implementations, the bonding wires 300 may include the first bonding wires 300-1 corresponding to the first semiconductor chip 200-1, the second bonding wires 300-2 corresponding to the second semiconductor chip 200-2, and the third bonding wires 300-3 corresponding to the third semiconductor chip 200-3. In addition, as shown in FIG. 2A, the bonding wires 300 may include metal wires 310 and wire coating layers 320W. The metal wires 310 may include a metal as the name thereof implies. For example, the metal wires 310 may include gold (Au), silver (Ag), copper (Cu), or the like. However, the material of the metal wires 310 is not limited thereto.

The wire coating layers 320W may cover the metal wires 310. For example, the wire coating layers 320W may cover exposed surfaces of the metal wires 310. Therefore, portions of the metal wires 310 covered by the adhesive layers 250 may not be covered by the wire coating layers 320W.

In the semiconductor package 1000 of some implementations, the wire coating layers 320W may be part of a coating layer 320. For example, the coating layer 320 may include the wire coating layers 320W, a chip coating layer 320C, and a substrate coating layer 320S. As described above, the wire coating layers 320W may cover the metal wires 310 and may form the bonding wires 300 together with the metal wires 310. The chip coating layer 320C may cover exposed outer surfaces of the first to third semiconductor chips 200-1 to 200-3 of the chip stack structure 200. For example, the chip coating layer 320C may cover the lateral surfaces of the first to third semiconductor chips 200-1 to 200-3 and an upper surface of the third semiconductor chip 200-3. In addition, the chip coating layer 320C may cover exposed lateral surfaces of the adhesive layers 250. The substrate coating layer 320S may cover the upper surface of the package substrate 100.

As shown in FIGS. 2A to 2C, the coating layer 320 may include a first insulating layer 322 and a second insulating layer 324. The first insulating layer 322 may directly cover the metal wires 310, an exposed surface of the chip stack structure 200, and the upper surface of the package substrate 100. The second insulating layer 324 may cover the first insulating layer 322 that is on the metal wires 310, the exposed surface of the chip stack structure 200, and the upper surface of the package substrate 100.

The first insulating layer 322 may include a material capable of improving electrical characteristics of the bonding wires 300. For example, the first insulating layer 322 may include a material capable of preventing crosstalk between adjacent bonding wires 300. For example, the first insulating layer 322 may include a high-k dielectric material. Examples of the high-k dielectric material may include HfO₂, HfSiO, HfSiON, HfTaO, HfTiO, HfZrO, ZrO₂, Al₂O₃, TiO₂, Ta₂O₅, hafnium oxide-aluminum oxide (HfO₂-Al₂O₃) alloys, other high-k dielectric materials, and/or combinations thereof.

The second insulating layer 324 may include a material capable of improving insulation characteristics of the bonding wires 300. For example, the second insulating layer 324 may include a material capable of preventing a short circuit between adjacent bonding wires 300. For example, the second insulating layer 324 may include an oxide insulating material or a polymer. For example, the oxide insulating material may include a silicon oxide such as SiO₂, or a metal oxide such as TiO₂ or Al₂O₃. The polymer may include, for example, Parylene. However, the oxide insulating material and the polymer are not limited to the materials listed above.

The sealing material 400 may cover and seal the chip stack structure 200 and the bonding wires 300 that are provided on the package substrate 100. The sealing material 400 may seal the first to third semiconductor chips 200-1 to 200-3 of the chip stack structure 200 and may protect the first to third semiconductor chips 200-1 to 200-3 of the chip stack structure 200 from external physical and chemical agents. The sealing material 400 may include an insulating material, for example, a thermosetting resin such as an epoxy resin or a thermoplastic resin such as polyimide. In addition, the sealing material 400 may include a resin material, such as an ABF, FR4, or BT resin, in which a reinforcement material such as an inorganic filler is contained in a thermosetting or thermoplastic resin. Furthermore, the sealing material 400 may include a molding material such as an epoxy molding compound (EMC), or a photosensitive material such as a photo imageable encapsulant (PIE). In the semiconductor package 1000 of some implementations, the sealing material 400 may include, for example, an EMC. However, the material of the sealing material 400 is not limited to the materials listed above.

The external connection terminals 500 may be disposed on a lower surface of the package substrate 100. The external connection terminals 500 may be electrically connected to the wires of the wiring layer of the package substrate 100 through the lower substrate pads 110d. The semiconductor package 1000 of some implementations may be mounted on a package substrate of an external system or on a main board of an electronic device such as a mobile device through the external connection terminals 500. The external connection terminals 500 may include a conductive material. For example, the external connection terminals 500 may include at least one selected from the group consisting of solder, tin (Sn), silver (Ag), copper (Cu), and aluminum (Al). In the semiconductor package 1000 of some implementations, the external connection terminals 500 may include, for example, solder. In some implementations, the external connection terminals 500 may each include a pillar and solder.

The semiconductor package 1000 of some implementations may include the coating layer 320 that covers the metal wires 310, the chip stack structure 200, and the package substrate 100. In addition, the coating layer 320 may include the first insulating layer 322 for improving electrical characteristics such as crosstalk prevention, and the second insulating layer 324 for improving insulation characteristics such as short-circuit prevention. Therefore, in the semiconductor package 1000 of some implementations, the bonding wires 300, which include the metal wires 310 and the wire coating layers 320W covering the metal wires 310, may exhibit improved electrical characteristics and may be free from short circuits between adjacent bonding wires 300. As a result, the semiconductor package 1000 of some implementations may exhibit improved SI and power integrity (PI) characteristics, and have a fine pad pitch.

For reference, the term “pad pitch” may herein refer to the pitch of chip pads on a semiconductor chip. Semiconductor packages of the related art have limitations in reducing the pitch of chip pads due to short-circuit issues between adjacent bonding wires. However, in the semiconductor package 1000 of some implementations, the bonding wires 300 include the coating layer 320, that is, the wire coating layers 320W, thereby resolving short-circuit issues between adjacent bonding wires 300 and reducing the pitch between the chip pads 210. That is, a fine pad pitch may be realized.

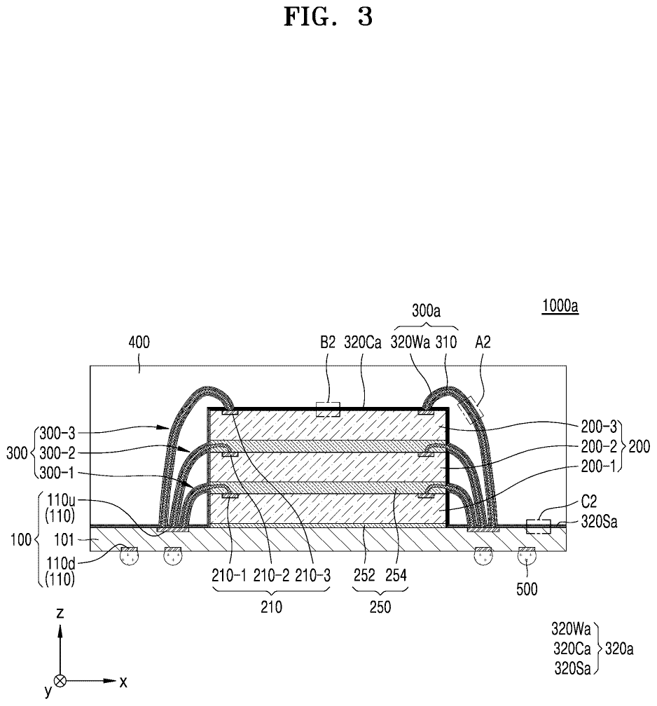

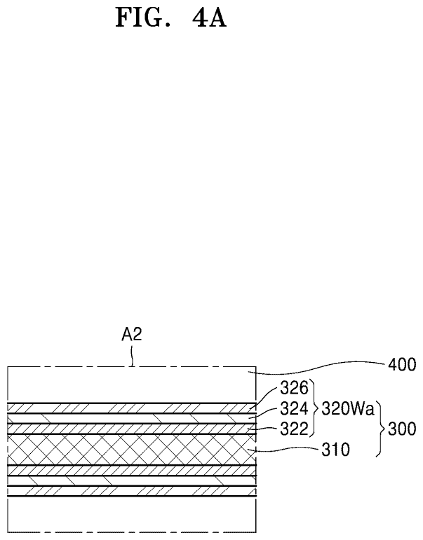

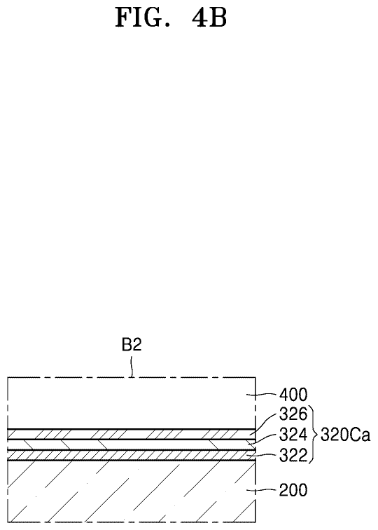

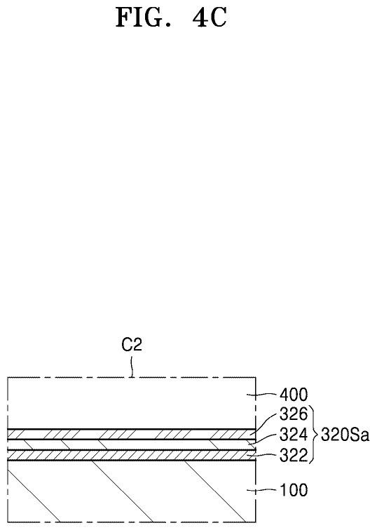

FIG. 3 is a cross-sectional view illustrating a semiconductor package 1000a according to an implementation, and FIGS. 4A to 4C are enlarged views illustrating portions A2, B2, and C2 of FIG. 3. Descriptions that are substantially the same as those given with reference to FIGS. 1 to 2C will be briefly discussed or omitted.

Referring to FIGS. 3 to 4C, the semiconductor package 1000a of some implementations may differ from the semiconductor package 1000 of FIG. 1 in the structure of a coating layer 320a. For example, the semiconductor package 1000a of some implementations may include a package substrate 100, a chip stack structure 200, bonding wires 300a, a sealing material 400, and external connection terminals 500. The package substrate 100, the chip stack structure 200, the sealing material 400, and the external connection terminals 500 are the same as described for the semiconductor package 1000 shown in FIG. 1.

In the semiconductor package 1000a of some implementations, bonding wires 300a may include metal wires 310 and wire coating layers 320Wa. The metal wires 310 are the same as described for the metal wires 310 of the bonding wires 300 of the semiconductor package 1000 shown in FIG. 1. The wire coating layers 320Wa may cover the metal wires 310. For example, the wire coating layers 320Wa may cover exposed surfaces of the metal wires 310. Therefore, portions of the metal wires 310 are covered by adhesive layers 250 may not be covered by the wire coating layers 320Wa.

In the semiconductor package 1000a of some implementations, the wire coating layers 320Wa may be part of the coating layer 320a. For example, the coating layer 320a may include the wire coating layers 320Wa, a chip coating layer 320Ca, and a substrate coating layer 320Sa. As described above, the wire coating layers 320Wa may cover the metal wires 310 and may form the bonding wires 300a together with the metal wire 310. The chip coating layer 320Ca may cover exposed outer surfaces of first to third semiconductor chips 200-1 to 200-3 of the chip stack structure 200. For example, the chip coating layer 320Ca may cover lateral surfaces of the first to third semiconductor chips 200-1 to 200-3 and an upper surface of the third semiconductor chip 200-3. In addition, the chip coating layer 320Ca may cover exposed lateral surfaces of the adhesive layers 250. The substrate coating layer 320Sa may cover an upper surface of the package substrate 100.

As shown in FIGS. 4A and 4B, the coating layer 320a may include a first insulating layer 322, a second insulating layer 324, and a barrier layer 326. The first insulating layer 322 and the second insulating layer 324 are the same as described for the first insulating layer 322 and the second insulating layer 324 of the coating layer 320 of the semiconductor package 1000 shown in FIG. 1.

The barrier layer 326 may cover the second insulating layer 324. The barrier layer 326 may include a material capable of enhancing adhesion with the sealing material 400. For example, the barrier layer 326 may include Ti, TiN, or the like. However, the material of the barrier layer 326 is not limited to the materials stated above. In some implementations, the barrier layer 326 may include a multilayered structure such as Ti/TiN.

The semiconductor package 1000a of some implementations may include the coating layer 320a that covers the metal wires 310, the chip stack structure 200, and the package substrate 100. In addition, the coating layer 320a may include the first insulating layer 322, the second insulating layer 324, and the barrier layer 326 for enhancing adhesion. Therefore, in the semiconductor package 1000a of some implementations, the sealing material 400 may be more firmly adhered to the bonding wires 300a, the chip stack structure 200, and the package substrate 100. Therefore, the semiconductor package 1000a of some implementations may be free from defects such as delamination and lifting, and may thus exhibit enhanced strength and process reliability. As a result, the semiconductor package 1000a of some implementations may exhibit improved SI and PI characteristics, realize a fine pad pitch, and improve process reliability and package strength.

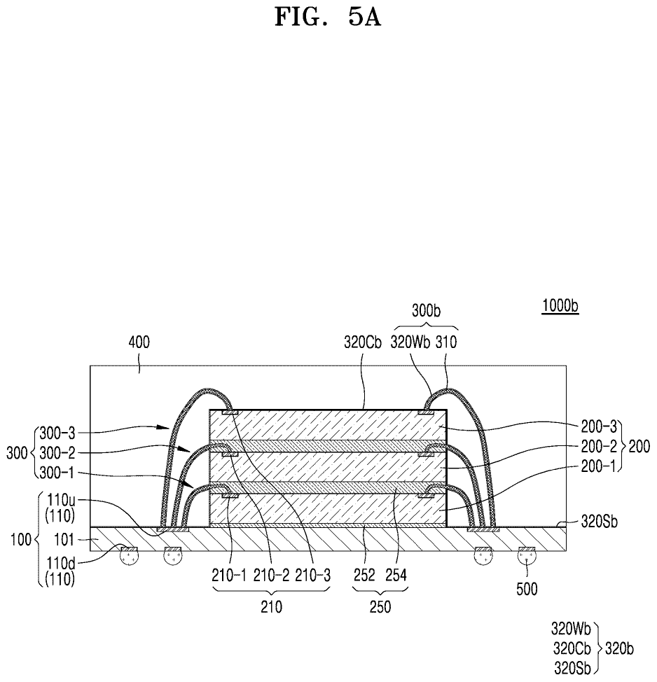

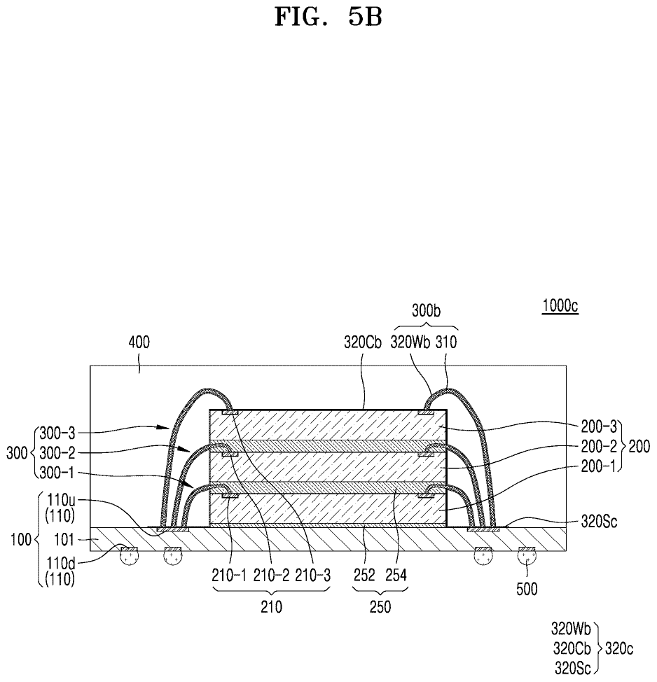

FIGS. 5A and 5B are cross-sectional views illustrating semiconductor packages 1000b and 1000c according to implementations. Descriptions that are substantially the same as those given with reference to FIGS. 1 to 4C will be briefly discussed or omitted.

Referring to FIG. 5A, the semiconductor package 1000b of some implementations may differ from the semiconductor package 1000 shown in FIG. 1 in the structure of a coating layer 320b. For example, the semiconductor package 1000b of some implementations may include a package substrate 100, a chip stack structure 200, bonding wires 300b, a sealing material 400, and external connection terminals 500. The package substrate 100, the chip stack structure 200, the sealing material 400, and the external connection terminals 500 are the same as described for the semiconductor package 1000 shown in FIG. 1.

In the semiconductor package 1000b of some implementations, the bonding wires 300b may include metal wires 310 and wire coating layers 320Wb. The metal wires 310 are the same as described for the metal wires 310 of the bonding wires 300 of the semiconductor package 1000 shown in FIG. 1. The wire coating layers 320Wb may cover the metal wires 310. For example, the wire coating layers 320Wb may cover exposed surfaces of the metal wires 310. Therefore, portions of the metal wires 310 that are covered by adhesive layers 250 may not be covered by the wire coating layers 320Wb.

In the semiconductor package 1000b of some implementations, the wire coating layers 320Wb may be part of the coating layer 320b. For example, the coating layer 320b may include the wire coating layers 320Wb, a chip coating layer 320Cb, and a substrate coating layer 320Sb. As described above, the wire coating layers 320Wb may cover the metal wires 310 and may form the bonding wires 300b together with the metal wires 310. The chip coating layer 320Cb may cover exposed outer surfaces of first to third semiconductor chips 200-1 to 200-3 of the chip stack structure 200. For example, the chip coating layer 320Cb may cover lateral surfaces of the first to third semiconductor chips 200-1 to 200-3 and an upper surface of the third semiconductor chip 200-3. In addition, the chip coating layer 320Cb may cover exposed lateral surfaces of the adhesive layers 250. The substrate coating layer 320Sb may cover an upper surface of the package substrate 100.

The coating layer 320b may include a single insulating layer. The coating layer 320b may include an insulating material for improving insulation characteristics. For example, the coating layer 320b may include substantially the same material as the second insulating layer 324 of the coating layer 320 or 320a of the semiconductor package 1000 or 1000a shown in FIG. 1 or 3. For example, the coating layer 320b may include a silicon oxide such as SiO₂, a metal oxide such as TiO₂ or Al₂O₃, or a polymer such as Parylene. However, the material of the coating layer 320b is not limited to the materials stated above. In some implementations, the coating layer 320b may include an insulating material for improving electrical characteristics.

The semiconductor package 1000b of some implementations includes the coating layer 320b including a single insulating layer, and thus, the coating layer 320b may be formed through a single coating process. Therefore, the semiconductor package 1000b of some implementations may simplify processes while exhibiting improved SI and PI characteristics and realizing a fine pad pitch.

Referring to FIG. 5B, the semiconductor package 1000c of some implementations may differ from the semiconductor package 1000b shown in FIG. 5A in layout regions of a coating layer 320c. For example, the semiconductor package 1000c of some implementations may include a package substrate 100, a chip stack structure 200, bonding wires 300b, a sealing material 400, and external connection terminals 500. The package substrate 100, the chip stack structure 200, the sealing material 400, and the external connection terminals 500 are the same as described for the semiconductor package 1000 shown in FIG. 1. In addition, the bonding wires 300b are the same as described for the bonding wires 300b of the semiconductor package 1000b shown in FIG. 5A.

In the semiconductor package 1000c of some implementations, the coating layer 320c may include wire coating layers 320Wb, a chip coating layer 320Cb, and a substrate coating layer 320Sc. The wire coating layers 320Wb and the chip coating layer 320Cb are the same as described for the wire coating layers 320Wb and the chip coating layer 320Cb of the coating layer 320b of the semiconductor package 1000b shown in FIG. 5A.

As shown in FIG. 5B, the substrate coating layer 320Sc may cover only a portion of an upper surface of the package substrate 100. For example, the substrate coating layer 320Sc may cover upper substrate pads 110u and a portion of the upper surface of the package substrate 100 around the upper substrate pads 110u. The portion of the upper surface of the package substrate 100 around the upper substrate pads 110u may include a region between the chip stack structure 200 and the upper substrate pads 110u and a region adjacent to the upper substrate pads 110u in a direction away from the chip stack structure 200.

The structure of the substrate coating layer 320Sc may result from a coating process performed in a state in which the upper substrate pads 110u of the package substrate 100 and the surface portion around the upper substrate pads 110u are exposed, while the remaining surface portion is covered with a mask. In addition, although the structure of the substrate coating layer 320Sc is applied to the coating layer 320c having a single insulating layer, the structure of the substrate coating layer 320Sc is not limited thereto. For example, the structure of the substrate coating layer 320Sc may be applied to the coating layer 320 having a dual-insulating-layer structure in the semiconductor package 1000 shown in FIG. 1 and the coating layer 320a having a triple-insulating-layer structure in the semiconductor package 1000a shown in FIG. 3.

The semiconductor package 1000c of some implementations includes the coating layer 320c, and the substrate coating layer 320Sc of the coating layer 320c may cover only the upper substrate pads 110u and the portion of the upper surface of the package substrate 100 around the upper substrate pads 110u. Therefore, defects such as attachment failure of the external connection terminals 500 provided on a lower surface of the package substrate 100, delamination of the sealing material 400, or void formation may be prevented. As a result, the semiconductor package 1000c of some implementations may exhibit improved SI and PI characteristics, realize a fine pad pitch, and improve process reliability and package strength.

FIGS. 6A to 6C are cross-sectional views illustrating semiconductor packages 1000d, 1000e, and 1000f according to implementations. Descriptions that are substantially the same as those given with reference to FIGS. 1 to 5B will be briefly discussed or omitted.

Referring to FIG. 6A, the semiconductor package 1000d of some implementations may differ from the semiconductor package 1000a shown in FIG. 3 in the arrangement structure of bonding wires 300a. For example, the semiconductor package 1000d of some implementations may include a package substrate 100, a chip stack structure 200, the bonding wires 300a, a sealing material 400, and external connection terminals 500. The package substrate 100, the chip stack structure 200, the sealing material 400, and the external connection terminals 500 are the same as described for the semiconductor package 1000a shown in FIG. 3.

In the semiconductor package 1000d of some implementations, the bonding wires 300a may be arranged on only the left side of the chip stack structure 200 in a x-direction. For example, in the semiconductor package 1000d of some implementations, upper substrate pads 110u of the package substrate 100 may be positioned on the left side of the chip stack structure 200 in the x-direction and arranged in a y-direction. In addition, chip pads 210 of each of first to third semiconductor chips 200-1 to 200-3 of the chip stack structure 200 may also be positioned adjacent to the left side in the x-direction and arranged in the y-direction. Therefore, on the left side of the chip stack structure 200 in the x-direction, the bonding wires 300a may connect the upper substrate pads 110u of the package substrate 100 to the chip pads 210 of each of the first to third semiconductor chips 200-1 to 200-3.

In the semiconductor package 1000d of some implementations, a coating layer 320a may have a triple-insulating-layer structure including a first insulating layer 322, a second insulating layer 324, and a barrier layer 326. However, the coating layer 320a is not limited thereto. The coating layer 320a may have a dual-insulating-layer structure including a first insulating layer 322 and a second insulating layer 324, like the coating layer 320 of the semiconductor package 1000 shown in FIG. 1, or a single-insulating-layer structure like the coating layer 320b of the semiconductor package 1000b shown in FIG. 5A. In addition, like the coating layer 320c of the semiconductor package 1000c shown in FIG. 5B, a substrate coating layer 320Sa of the coating layer 320a may cover only a portion of an upper surface of the package substrate 100. For example, the substrate coating layer 320Sa may cover only the upper substrate pads 110u on the left side of the chip stack structure 200 in the x-direction and a region around the upper substrate pads 110u. Moreover, the substrate coating layer 320Sa may not cover the upper surface of the package substrate 100 on the right side of the chip stack structure 200 in the x-direction.

In addition, the placement of the bonding wires 300a is not limited to being on only the left side of the chip stack structure 200 in the x-direction. For example, the bonding wires 300a may be positioned on one side of the chip stack structure 200 in the x-direction or on one side of the chip stack structure 200 in the y-direction. Additionally, the bonding wires 300a may also be positioned on both sides of the chip stack structure 200 in the x-direction and on both sides of the chip stack structure 200 in the y-direction.

Referring to FIG. 6B, the semiconductor package 1000e of some implementations may differ from the semiconductor package 1000d shown in FIG. 6A in terms of a chip stack structure 200a. For example, the semiconductor package 1000e of some implementations may include a package substrate 100, the chip stack structure 200a, bonding wires 300a, a sealing material 400, and external connection terminals 500. The package substrate 100, the sealing material 400, and the external connection terminals 500 are the same as described for the semiconductor package 1000a shown in FIG. 3. In addition, the bonding wires 300a are the same as described for the bonding wires 300a of the semiconductor package 1000d shown in FIG. 6A.

In the semiconductor package 1000e of some implementations, the chip stack structure 200a may have a stair-step configuration in which first to third semiconductor chips 200-1 to 200-3 are stacked in a stepped manner. For example, the chip stack structure 200a may have a stair-step configuration in which the first to third semiconductor chips 200-1 to 200-3 are sequentially shifted to the right side in an x-direction as the first to third semiconductor chips 200-3 are stacked upward. In addition, each of the first to third semiconductor chips 200-1 to 200-3 may have chip pads 210 positioned adjacent to the left side in the x-direction. The chip pads 210 of each of the first to third semiconductor chips 200-1 to 200-3 may be exposed upward owing to the stair-step configuration. Therefore, on the left side of the chip stack structure 200a in the x-direction, the bonding wires 300a may connect the chip pads 210 of each of the first to third semiconductor chips 200-1 to 200-3 to substrate pads 110 of the package substrate 100. In addition, because the chip pads 210 are exposed, metal wires 310 of the bonding wires 300a may not be covered by adhesive layers 250a, and thus, wire coating layers 320Wa of the bonding wires 300a may entirely cover the metal wires 310. In addition, the adhesive layers 250a may have substantially the same thickness across all of the first to third semiconductor chips 200-1 to 200-3. For example, the adhesive layers 250a may include a DAF.

In the semiconductor package 1000e of some implementations, a coating layer 320a may have a triple-insulating-layer structure including a first insulating layer 322, a second insulating layer 324, and a barrier layer 326. However, the coating layer 320a is not limited thereto. For example, the coating layer 320a may have a dual-insulating-layer structure including a first insulating layer 322 and a second insulating layer 324 like the coating layer 320 of the semiconductor package 1000 shown in FIG. 1, or a single-insulating-layer structure like the coating layer 320b of the semiconductor package 1000b shown in FIG. 5A. In addition, like the coating layer 320c of the semiconductor package 1000c shown in FIG. 5B, a substrate coating layer 320Sa of the coating layer 320a may cover only a portion of an upper surface of the package substrate 100. For example, the substrate coating layer 320Sa may cover only upper substrate pads 110u on the left side of the chip stack structure 200a in the x-direction and a region around the upper surface pads 100u. Moreover, the substrate coating layer 320Sa may not cover the upper surface of the package substrate 100 on the right side of the chip stack structure 200 in the x-direction.

Referring to FIG. 6C, the semiconductor package 1000f of some implementations may differ from the semiconductor package 1000d of FIG. 6a in terms of a chip stack structure 200b. For example, the semiconductor package 1000f of some implementations may include a package substrate 100, the chip stack structure 200b, bonding wires 300a, a sealing material 400, and external connection terminals 500. The package substrate 100, the sealing material 400, and the external connection terminals 500 are the same as described for the semiconductor package 1000a shown in FIG. 3. In addition, the bonding wires 300a are the same as described for the bonding wires 300a of the semiconductor package 1000d shown in FIG. 6A.

In the semiconductor package 1000f of some implementations, the chip stack structure 200b may have a zigzag configuration in which first to third semiconductor chips 200-1 to 200-3 are stacked in a zigzag manner. For example, the chip stack structure 200b may have a zigzag configuration in which the first to third semiconductor chips 200-1 to 200-3 are sequentially offset left and right in an x-direction as the first to third semiconductor chips 200-1 to 200-3 are stacked upward. In addition, each of the first to third semiconductor chips 200-1 to 200-3 may have chip pads 210 positioned adjacent to either the left or right side in the x-direction. For example, the first semiconductor chip 200-1 and the third semiconductor chip 200-3 may have chip pads 210 positioned adjacent to the left side in the x-direction, and the second semiconductor chip 200-2 may have chip pads 210 disposed adjacent to the right side in the x-direction.

The chip pads 210 of each of the first to third semiconductor chips 200-1 to 200-3 may be exposed upward owing to the zigzag configuration. Therefore, on the left or right side of the chip stack structure 200a in the x-direction, the bonding wires 300a may connect the chip pads 210 of each of the first to third semiconductor chips 200-1 to 200-3 to substrate pads 110 of the package substrate 100. In addition, because the chip pads 210 are exposed, metal wires 310 of the bonding wires 300a may not be covered by adhesive layers 250a, and therefore, wire coating layers 320Wa of the bonding wires 300a may entirely cover the metal wires 310. In addition, the adhesive layers 250a may have substantially the same thickness across all of the first to third semiconductor chips 200-1 to 200-3. For example, the adhesive layers 250a may include a DAF.

In the semiconductor package 1000e of some implementations, a coating layer 320a may have a triple-insulating-layer structure including a first insulating layer 322, a second insulating layer 324, and a barrier layer 326. However, the coating layer 320a is not limited thereto. For example, the coating layer 320a may have a dual-insulating-layer structure including a first insulating layer 322 and a second insulating layer 324 like the coating layer 320 of the semiconductor package 1000 shown in FIG. 1, or a single-insulating-layer structure like the coating layer 320b of the semiconductor package 1000b shown in FIG. 5A. In addition, like the coating layer 320c of the semiconductor package 1000c shown in FIG. 5B, a substrate coating layer 320Sa of the coating layer 320a may cover only a portion of an upper surface of the package substrate 100. For example, the substrate coating layer 320Sa may cover only upper substrate pads 110u and a region around the upper substrate pads 110u.

Chip stack structures with a vertical configuration having aligned lateral surfaces, a stair-step configuration, and a zigzag configuration have been described. However, chip stack structures are not limited thereto. For example, when the chip stack structure with a stair-step configuration includes many semiconductor chips, the chip stack structure may be modified to have a staggered stair-step configuration in which the direction of steps changes at an upper side. In addition, the chip stack structure with a zigzag configuration may zigzag left and right in the x-direction and also back and forth in the y-direction.

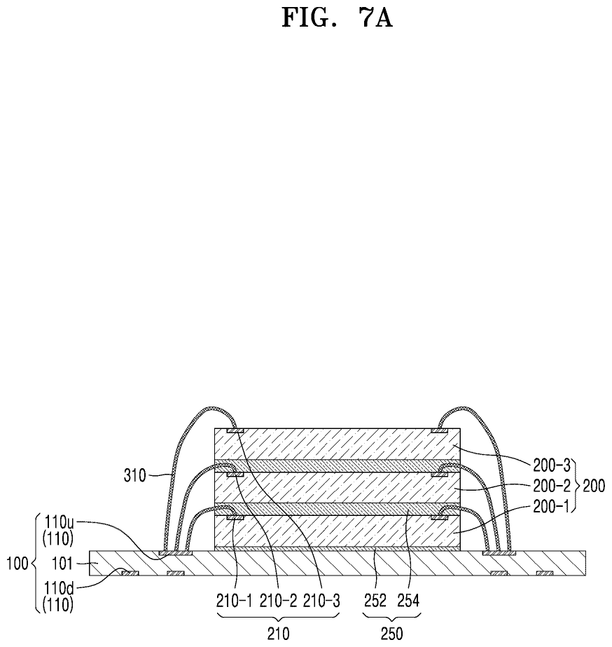

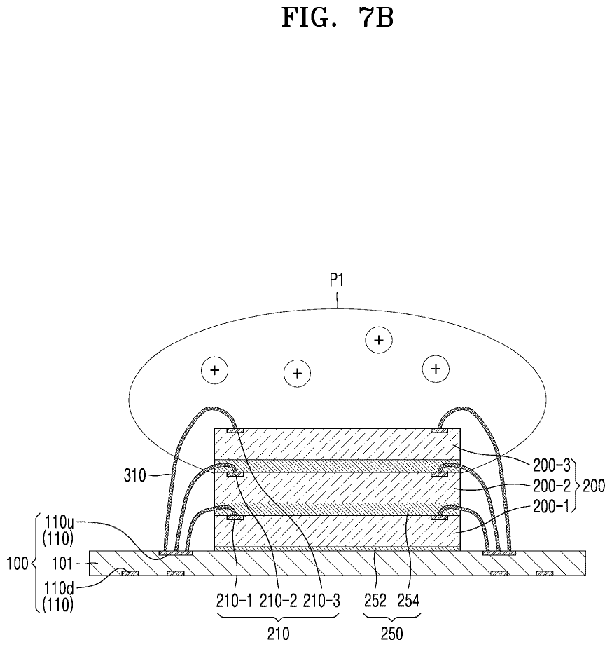

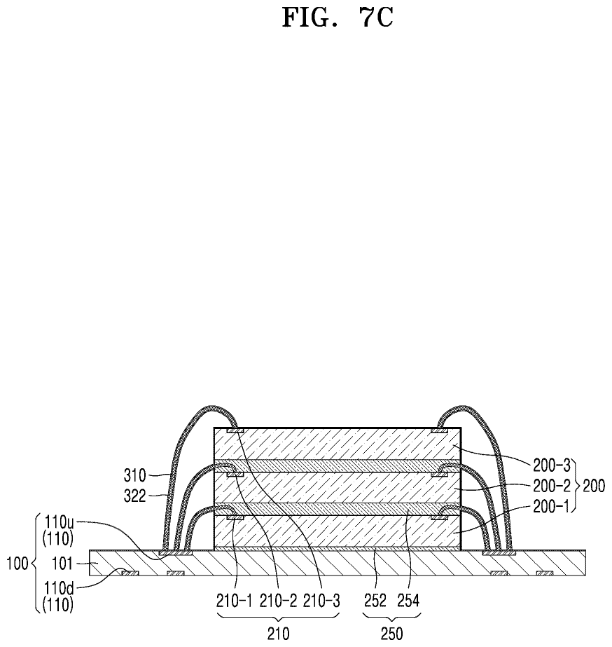

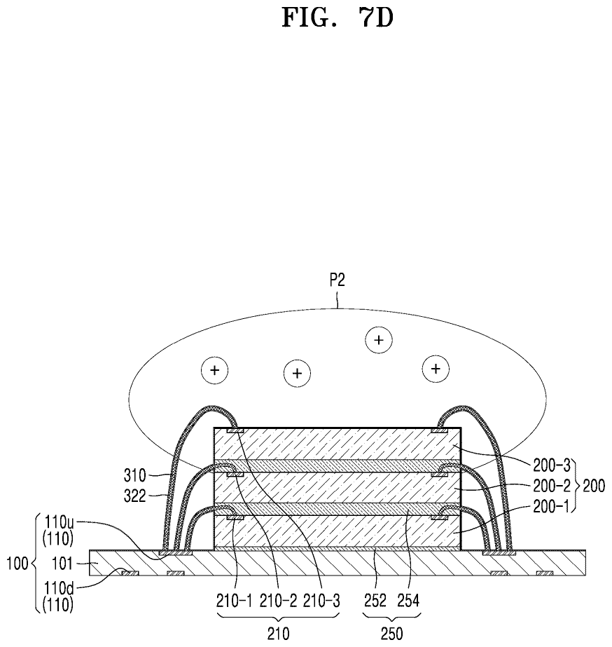

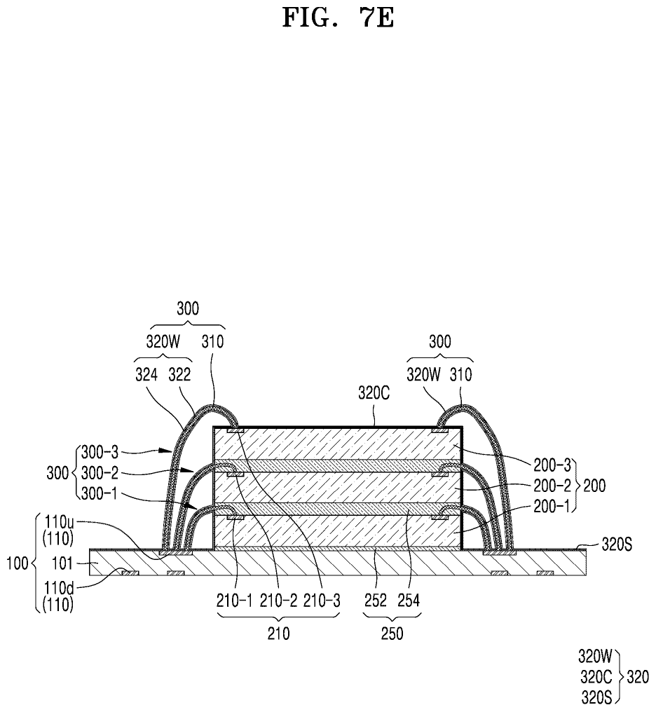

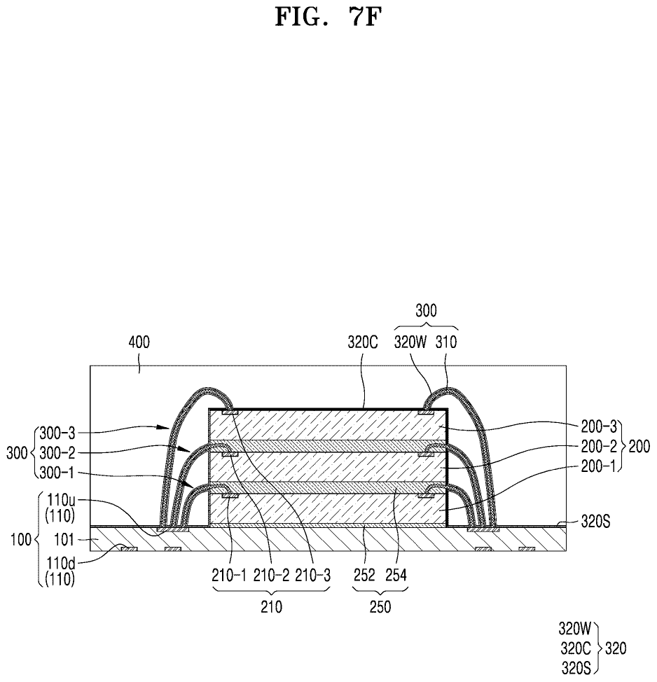

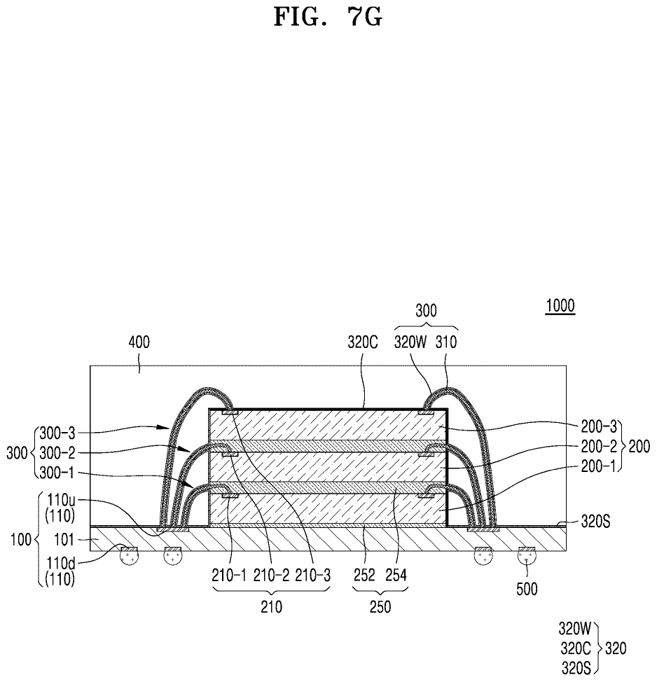

FIGS. 7A to 7G are cross-sectional views schematically illustrating processes in a method of manufacturing a semiconductor package, according to an implementation. The method of manufacturing a semiconductor package will now be described with reference to FIGS. 7A to 7G together with FIGS. 1 to 2C, and Descriptions that are substantially the same as those given with reference to FIGS. 1 to 6C will be briefly discussed or omitted.

Referring to FIG. 7A, in the method of manufacturing a semiconductor package according to some implementations, a chip stack structure 200 is first mounted on a package substrate 100 through a wire bonding process. The package substrate 100 may include a substrate body layer 101 and substrate pads 110. The package substrate 100 is the same as described for the package substrate 100 of the semiconductor package 1000 shown in FIG. 1. The chip stack structure 200 may include first to third semiconductor chips 200-1 to 200-3 and may have a vertically aligned lateral surface configuration. The chip stack structure 200 is the same as described for the chip stack structure 200 of the semiconductor package 1000 shown in FIG. 1.

Each of the first to third semiconductor chips 200-1 to 200-3 of the chip stack structure 200 may be connected to the package substrate 100 via metal wires 310. For example, chip pads 210 of each of the first to third semiconductor chip 200-1 to 200-3 may be connected to upper substrate pads 110u of the package substrate 100 via the metal wires 310.

The wire bonding process for mounting the chip stack structure 200 on the package substrate 100 is performed as follows. First, the first semiconductor chip 200-1 is bonded to the package substrate 100 through an adhesive layer 250, for example, a first adhesive layer 252, and then, first chip pads 210-1 of the first semiconductor chip 200-1 are connected to the upper substrate pads 110u of the package substrate 100 by using metal wires 310 by wire bonding. Thereafter, the second semiconductor chip 200-2 is placed on and bonded to the first semiconductor chip 200-1 via an adhesive layer 250, for example, a second adhesive layer 254, and then, second chip pads 210-2 of the second semiconductor chip 200-2 are connected to the upper substrate pads 110u of the package substrate 100 by using metal wires 310 by wire bonding. Subsequently, the third semiconductor chip 200-3 is placed and bonded to the second semiconductor chip 200-2 via a second adhesive layer 254, and third chip pads 210-3 of the third semiconductor chip 200-3 are connected to the upper substrate pads 110u of the package substrate 100 by using metal wires 310 by wire bonding.

In the semiconductor packages 1000e and 1000f shown in FIGS. 6B and 6C, the chip stack structures 200a and 200b have a structure in which the chip pads 210 of each of the first to third semiconductor chips 200-1 to 200-3 are exposed. In this case, the wire bonding process may be performed on all of the first to third semiconductor chips 200-1 to 200-3 after stacking all of the first to third semiconductor chips 200-1 to 200-3. However, implementations are not limited thereto. For example, as described for the chip stack structure 200 shown in FIG. 7A, chip placement and wire bonding may be performed chip by chip.

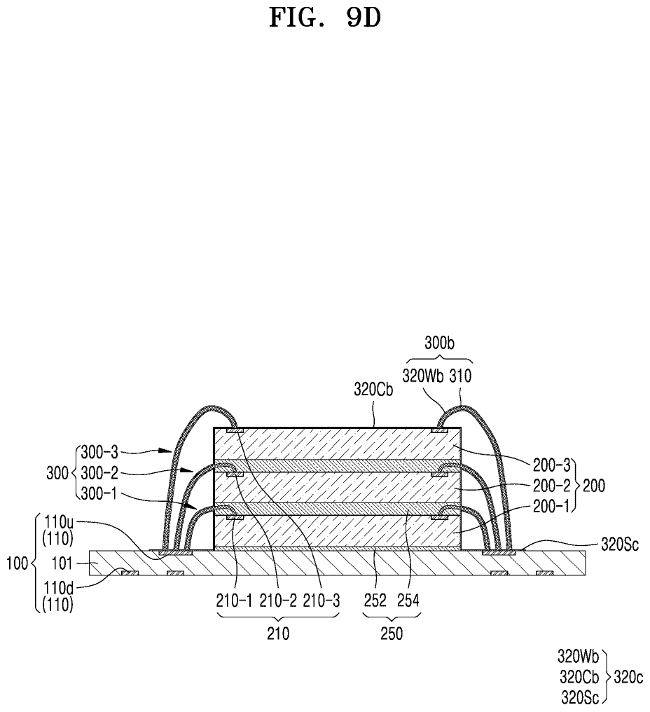

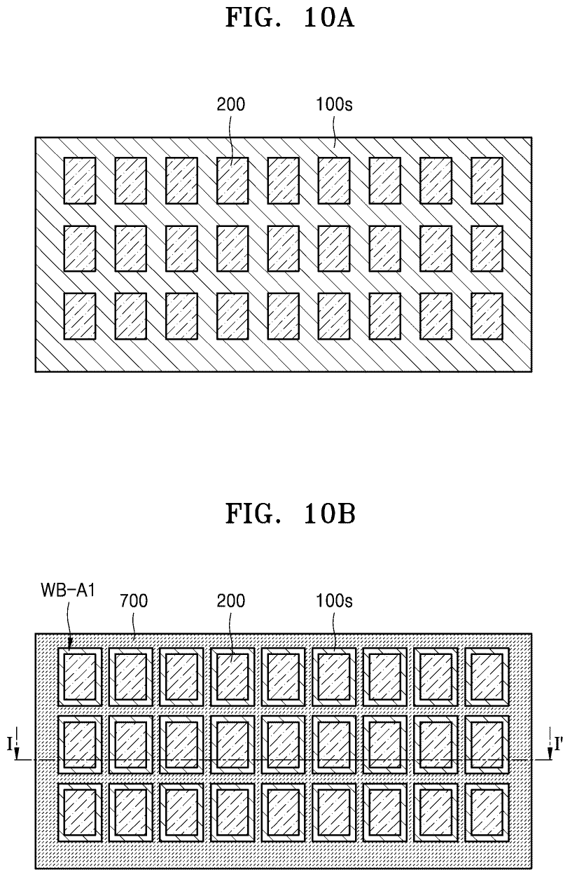

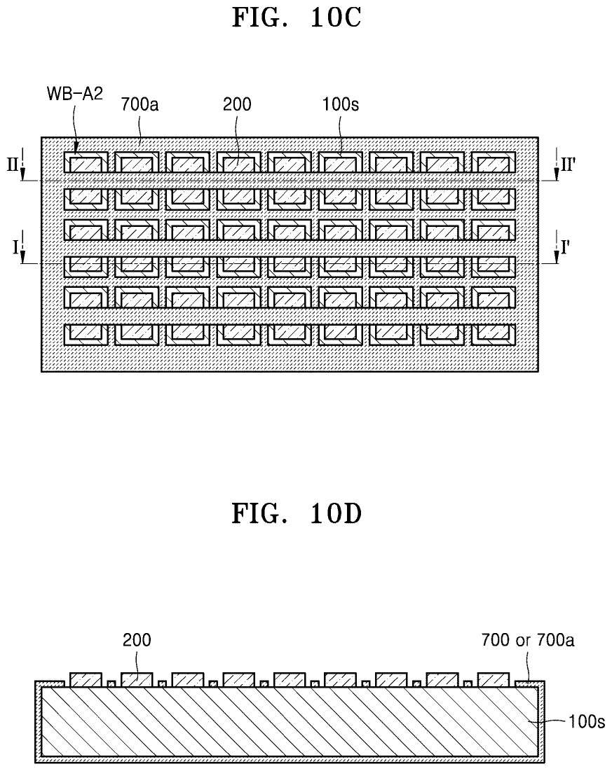

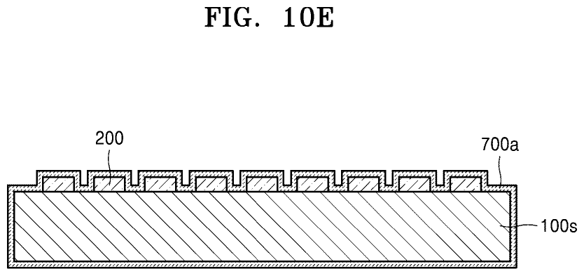

For reference, a plurality of chip stack structures 200 may be mounted on a strip substrate 100s (refer to FIG. 10A). Here, the strip substrate 100s may include a plurality of package substrates 100 arranged in a two-dimensional array structure. That is, a plurality of chip stack structures 200 may be arranged on the strip substrate 100s, and after a series of processes, the plurality of chip stack structures 200 may be separated through a sawing process. In this manner, a package substrate 100 and a semiconductor package 1000 including the package substrate 100 may be completely manufactured.

Referring to FIG. 7B, after mounting the chip stack structure 200, a first coating process is performed to form a first insulating layer 322. The first coating process may be performed using at least one of physical vapor deposition (PVD), chemical vapor deposition (CVD), or atomic layer deposition (ALD). A typical example of PVD may be sputtering. In FIG. 7B, P1 may refer to plasma used in a CVD process or the like. In addition, “+” may refer to ions in the plasma. The plasma may include, in addition to ions, components such as radicals, electrons, and ultraviolet rays. In general, charged ions may be mainly used as a deposition material.

Referring to FIG. 7C, the first insulating layer 322 may be coated on the metal wires 310, an exposed surface of the chip stack structure 200, and an upper surface of the package substrate 100 through the first coating process. For example, the first insulating layer 322 may cover the metal wires 310, the exposed surface of the chip stack structure 200, and the upper surface of the package substrate 100.

As described above, the first insulating layer 322 may include a material capable of improving electrical characteristics. For example, the first insulating layer 322 may include a material capable of preventing crosstalk between adjacent bonding wires 300. For example, the first insulating layer 322 may include a high-k dielectric material. Examples of the high-k dielectric material may include HfO₂, HfSiO, HfSiON, HfTaO, HfTiO, HfZrO, ZrO₂, Al₂O₃, TiO₂, Ta₂O₅, hafnium oxide-aluminum oxide (HfO₂-Al₂O₃) alloys, other high-k dielectric materials, and/or combinations thereof.

For reference, a lower surface of the package substrate 100 may be covered by a mask or attached to a support substrate and may thus be not coated with the first insulating layer 322. In addition, as described above, the package substrate 100 may be finally formed by performing a sawing process on the strip substrate 100s to separate the package substrate 100. Thus, the first insulating layer 322 is illustrated as not being on a lateral surface of the package substrate 100. This may apply to a second insulating layer 324 and a barrier layer 326, which will be described below.

Referring to FIG. 7D, after coating the first insulating layer 322, a second coating process is performed to form the second insulating layer 324. The second coating process may also be performed using at least one of PVD, CVD, or ALD. For the PVD process, for example, a sputtering process may be used. In FIG. 7D, P2 may refer to plasma used in a CVD process or the like. In addition, “+” may refer to ions in the plasma.

Referring to FIG. 7E, the second insulating layer 324 may be coated on the first insulating layer 322 through the second coating process. For example, the second insulating layer 324 may cover the first insulating layer 322 that covers the metal wires 310, the exposed surface of the chip stack structure 200, and the upper surface of the package substrate 100.

As described above, the second insulating layer 324 may include a material capable of improving insulation characteristics of the bonding wires 300. For example, the second insulating layer 324 may include a material capable of preventing a short circuit between adjacent bonding wires 300. For example, the second insulating layer 324 may include an oxide insulating material or a polymer. The oxide insulating material may include, for example, a silicon oxide such as SiO₂, or a metal oxide such as TiO₂ or Al₂O₃. The polymer may include, for example, Parylene.

With the formation of the second insulating layer 324, a coating layer 320 may be completely formed. That is, the coating layer 320 may include the first insulating layer 322 and the second insulating layer 324. In addition, the coating layer 320 may include wire coating layers 320W, a chip coating layer 320C, and a substrate coating layer 320S. The wire coating layers 320W may cover the metal wires 310 and may form the bonding wires 300 together with the metal wires 310. In addition, the chip coating layer 320C may cover exposed outer surfaces of the first to third semiconductor chips 200-1 to 200-3 of the chip stack structure 200, and the substrate coating layer 320S may cover the upper surface of the package substrate 100.

Referring to FIG. 7F, after the formation of the coating layer 320, a sealing material 400 is formed to seal the chip stack structure 200 and the bonding wires 300 on the package substrate 100. The sealing material 400 is the same as described for the sealing material 400 of the semiconductor package 1000 in FIG. 1. In addition, the sealing material 400 may entirely seal all chip stack structures 200 and all corresponding bonding wires 300 that are provided on the strip substrate 100s.

Referring to FIG. 7G, after the formation of the sealing material 400, a soldering process may be performed to attach external connection terminals 500 to the lower surface of the package substrate 100. Thereafter, a sawing process may be performed to divide the strip substrate 100s and structures formed on the strip substrate 100s, thereby completing the manufacture of a semiconductor package 1000. For example, the semiconductor package 1000 may correspond to the semiconductor package 1000 shown in FIG. 1. In some implementations, the soldering process for attaching the external connection terminals 500 to the lower surface of the package substrate 100 may be performed after the dividing through the sawing process to prevent contamination of the external connection terminals 500.

Furthermore, in the method of manufacturing the semiconductor package 1000 according to some implementations, the processes shown in FIGS. 7B and 7C may be omitted. In this case, the semiconductor package 1000b shown in FIG. 5A may be manufactured through the processes shown in FIGS. 7A and 7D to 7G.

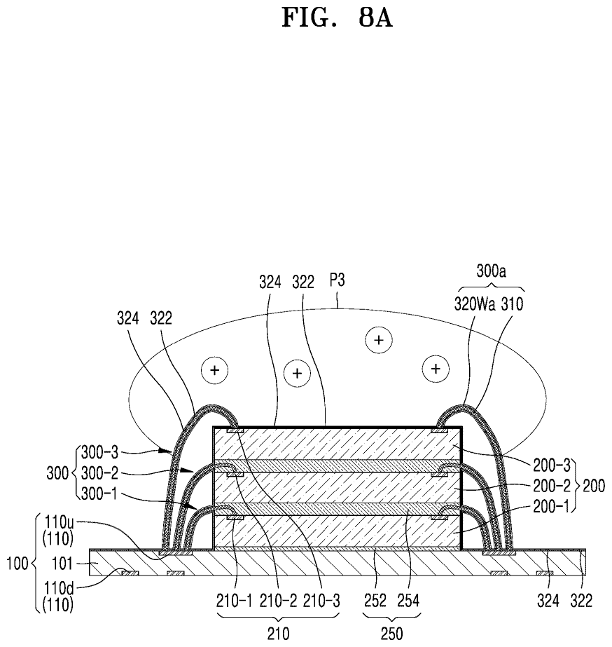

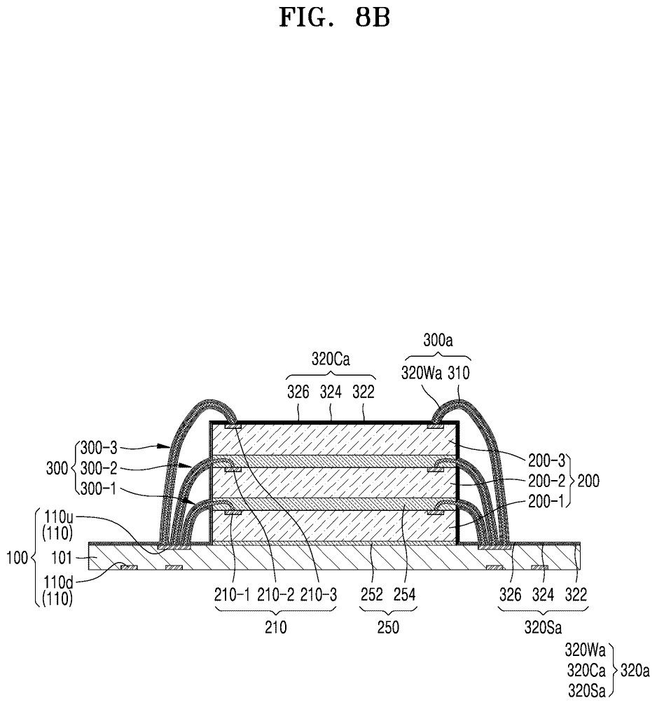

FIGS. 8A and 8B are cross-sectional views schematically illustrating processes in a method of manufacturing a semiconductor package, according to an implementation. The method of manufacturing a semiconductor package will now be described with reference to FIGS. 8A and 8B together with FIGS. 3 to 4C, and descriptions that are substantially the same as those given with reference to FIGS. 1 to 7G will be briefly discussed or omitted.

Referring to FIG. 8A, in the method of manufacturing a semiconductor package according to some implementations, the processes described with reference to FIGS. 7A to 7E are performed to form a first insulating layer 322 and a second insulating layer 324. Thereafter, a third coating process is performed to form a barrier layer 326. The third coating process may also be performed using at least one of PVD, CVD, or ALD. For the PVD process, for example, a sputtering process may be used. In FIG. 8A, P3 may refer to plasma used in a CVD process or the like. In addition, “+” may refer to ions in the plasma.

Referring to FIG. 8B, the barrier layer 326 may be coated on the second insulating layer 324 through the third coating process. For example, the barrier layer 326 may cover the second insulating layer 324 that covers metal wires 310, an exposed surface of a chip stack structure 200, and an upper surface of a package substrate 100.

As described above, the barrier layer 326 may include a material capable of enhancing adhesion with a sealing material 400. For example, the barrier layer 326 may include Ti, TiN, and the like. However, the material of the barrier layer 326 is not limited to the materials stated above. In some implementations, the barrier layer 326 may include a multilayer structure such as a Ti/TiN structure.

With the formation of the barrier layer 326, a coating layer 320a may be completely formed. That is, the coating layer 320a may include the first insulating layer 322, the second insulating layer 324, and the barrier layer 326. In addition, the coating layer 320a may include wire coating layers 320Wa, a chip coating layer 320Ca, and a substrate coating layer 320Sa. The wire coating layers 320Wa may cover the metal wires 310 and may form bonding wires 300a together with the metal wires 310. The chip coating layer 320Ca may cover exposed outer surfaces of first to third semiconductor chips 200-1 to 200-3 of the chip stack structure 200, and the substrate coating layer 320Sa may cover the upper surface of the package substrate 100.

Thereafter, the processes described with reference to FIGS. 7F and 7G may be performed to complete the manufacture of a semiconductor package 1000a. The semiconductor package 1000a may correspond to, for example, the semiconductor package 1000a shown in FIG. 3. Furthermore, in FIG. 7A, when the bonding wires 300a are arranged only on the left side of the chip stack structure 200 in the x-direction as shown in FIG. 6a, the semiconductor package 1000d shown in FIG. 6A may be manufactured through the processes shown in FIGS. 7A to 7G. Moreover, in FIG. 7A, when a chip stack structure 200a having a stair-step configuration or a chip stack structure 200b having a zigzag configuration is mounted on the package substrate 100, the semiconductor packages 1000e or 1000f shown in FIG. 6B or 6C may be manufactured through the processes shown in FIGS. 7A to 7G.

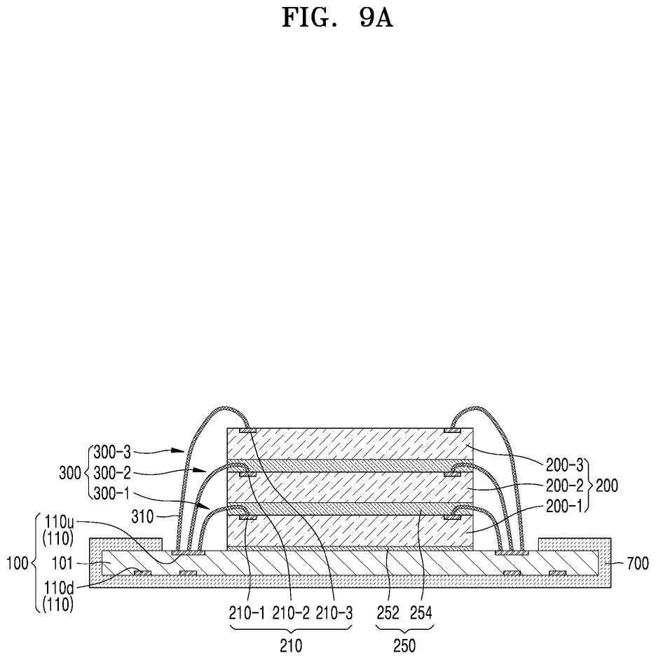

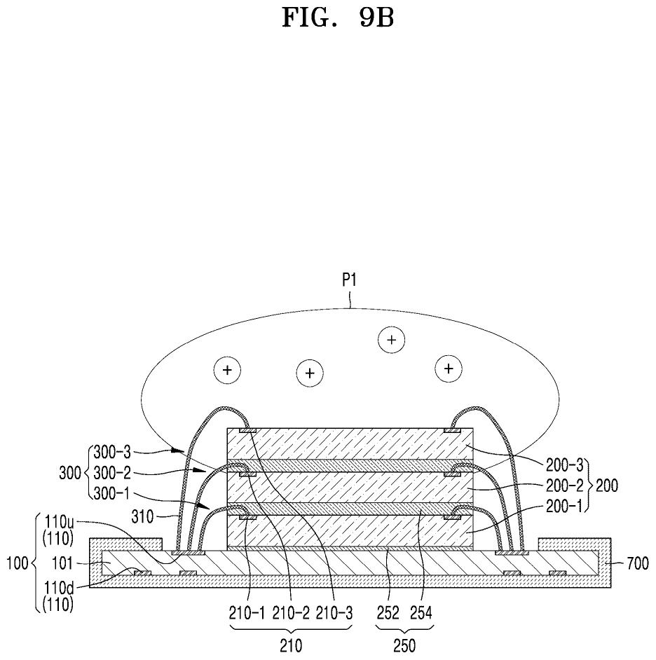

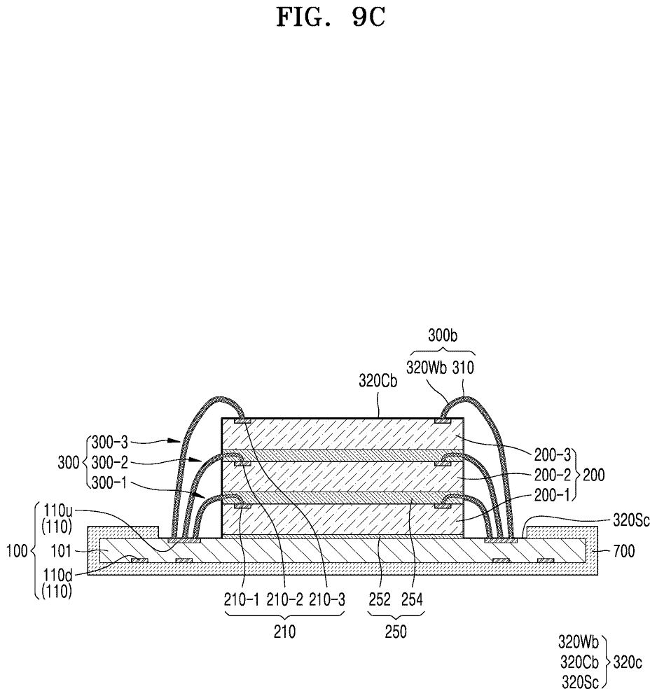

FIGS. 9A to 9D are cross-sectional views schematically illustrating processes in a method of manufacturing a semiconductor package, according to an implementation. The method of manufacturing a semiconductor package will now be described with reference to FIGS. 9A to 9D together with FIG. 5B, and descriptions that are substantially the same as those given with reference to FIGS. 1 to 8B will be briefly discussed or omitted.

Referring to FIG. 9A, in the method of manufacturing a semiconductor package according to some implementations, a chip stack structure 200 is mounted on a package substrate 100 through the process described with reference to FIG. 7A. The chip stack structure 200 is mounted as described with reference to FIG. 7A. Thereafter, a masking process is performed to form a mask 700 that covers lateral surfaces, a lower surface, and a portion of an upper surface of the package substrate 100. As shown in FIG. 9A, the mask 700 may not cover upper substrate pads 110u provided on the upper surface of the package substrate 100 and a region around the upper substrate pads 110u. Owing to the mask 700, a portion of the package substrate 100, covered by the mask 700, may not be coated during a subsequent coating process.

The mask 700 may include a material that is easy to pattern and remove. For example, the mask 700 may include photoresist (PR) or SR. However, the material of the mask 700 is not limited thereto.

For reference, the package substrate 100 shown in FIG. 9A may be a strip substrate (refer to 100s in FIG. 10A). However, for ease of illustration, the strip substrate 100s is illustrated in a size corresponding to the package substrate 100. The structure of the mask 700 formed on the strip substrate 100s through the masking process will be described with reference to FIGS. 10A to 10E.

Referring to FIG. 9B, after forming the mask 700, a first coating process is performed to form a coating layer 320c. The first coating process may be performed using at least one of PVD, CVD, or ALD. For the PVD process, for example, a sputtering process may be used. In FIG. 9B, P1 may refer to plasma used in a CVD process or the like. Additionally, “+” may refer to ions in the plasma.

Referring to FIG. 9C, through the first coating process, the coating layer 320c may be coated on metal wires 310, an exposed surface of the chip stack structure 200, and an upper surface of the package substrate 100. For example, the coating layer 320c may cover the metal wires 310, the exposed surface of the chip stack structure 200, and the upper surface of the package substrate 100.

The coating layer 320c may include substantially the same material as a second insulating layer 324. Therefore, the coating layer 320c may include a material capable of improving insulation characteristics of bonding wires 300b. For example, the coating layer 320c may include a material capable of preventing a short circuit between adjacent bonding wires 300b. For example, the coating layer 320c may include an oxide insulating material or a polymer. For example, the oxide insulating material may include a silicon oxide such as SiO₂ or a metal oxide such as TiO₂ or Al₂O₃. The polymer may include, for example, Parylene. In some implementations, the coating layer 320c may include an insulating material capable of improving electrical characteristics.

The coating layer 320c may have a single-insulating-layer structure. In addition, the coating layer 320c may include wire coating layers 320Wb, a chip coating layer 320Cb, and a substrate coating layer 320Sc. The wire coating layers 320Wb may cover the metal wires 310 and may form the bonding wires 300b together with the metal wires 310. In addition, the chip coating layer 320Cb may cover exposed outer surfaces of first to third semiconductor chips 200-1 to 200-3 of the chip stack structure 200, and the substrate coating layer 320Sc may cover the upper surface of the package substrate 100. The substrate coating layer 320Sc may cover only the upper substrate pads 110u and a portion around the upper substrate pads 110u on the upper surface of the package substrate 100.

In some implementations, a coating process may be performed twice or three times to form a coating layer 320 having a dual-insulating-layer structure like the coating layer 320 of the semiconductor package 1000 shown in FIG. 1 or a coating layer 320a having a triple-insulating-layer structure like the coating layer 320a of the semiconductor package shown in FIG. 3. However, due to the mask 700, a substrate coating layer 320S or 320Sa of the coating layer 320 having a dual-insulating-layer structure or the coating layer 320a having a triple-insulating-layer structure may cover only the upper substrate pads 110u and a portion around the upper substrate pads 110u on the upper surface of the package substrate 100.

Referring to FIG. 9D, after forming the coating layer 320c, the mask 700 is removed. Thereafter, the processes described with reference to FIGS. 7F and 7G are performed to complete the manufacture of a semiconductor package 1000c shown in FIG. 5B.

In the method of manufacturing a semiconductor package according to some implementations, owing to the mask 700, the coating layer 320c may not be formed on upper, lateral, and lower surfaces of the package substrate 100 except for the upper substrate pads 110u and a portion around the upper substrate pads 110u. Therefore, external connection terminals 500 may be firmly attached to the lower surface of the package substrate 100 without attachment defects. Furthermore, lifting or void formation between a sealing material 400 and the package substrate 100 may be prevented. As a result, the semiconductor package 1000c may have improved strength and reliability.

FIGS. 10A to 10E are plan views and cross-sectional views illustrating shapes of masks 700 and 700a in the process shown in FIG. 9A. For example, FIG. 10A is a plan view illustrating the strip substrate 100s on which chip stack structures 200 are mounted prior to the formation of the mask 700 or 700a, FIGS. 10B and 10C are plan views illustrating the strip substrate 100s after the formation of the mask 700 or 700a, FIG. 10D is a cross-sectional view taken along line I-I′ of FIG. 10B or 10C, and FIG. 10E is a cross-sectional view taken along line II-II′ of FIG. 10C.

Referring to FIG. 10A, the strip substrate 100s may include a plurality of package substrates arranged in a two-dimensional array structure. In addition, the chip stack structures 200 may be mounted corresponding to the package substrates. Each of the chip stack structures 200 may be mounted on a corresponding package substrate by, for example, wire bonding.

Referring to FIGS. 10B and 10D, the mask 700 may cover lower and lateral surfaces of the strip substrate 100s. The mask 700 may also cover an upper surface of the strip substrate 100s except for wire bonding regions WB-A1. The wire bonding regions WB-A1 may refer to regions of upper surfaces of the package substrates in which bonding wires are arranged. For example, referring to FIG. 10B, the wire bonding regions WB-A1 may correspond to regions of the upper surfaces of the package substrates that are located around the chip stack structures 200 and not covered by the mask 700. In the wire bonding regions WB-A1, upper substrate pads of the package substrates may be arranged. For reference, in FIGS. 10D and 10E, the chip stack structures 200 are illustrated in a simplified single-layer form without distinction between semiconductor chips.

Referring to FIGS. 10C to 10E, the mask 700a may cover the lower and lateral surfaces of the strip substrate 100s. In addition, the mask 700a may cover the upper surface of the strip substrate 100s and portions of upper surfaces of the chip stack structures 200 except for wire bonding regions WB-A2. The wire bonding regions WB-A2 may refer to regions of the upper surfaces of the package substrates in which bonding wires are arranged. For example, referring FIG. 10C, the wire bonding regions WB-A2 may correspond to regions of the upper surfaces of the package substrates that are located around the chip stack structures 200 and are not covered by the mask 700a. Furthermore, upper substrate pads of the package substrates may be arranged in the wire bonding regions WB-A2.

Because the mask 700a covers portions of the upper surfaces of the chip stack structures 200, a coating layer may not be formed on the portions of the upper surfaces of the chip stack structures 200 in a subsequent coating process. Therefore, adhesion between the chip stack structures 200 and a sealing material may be enhanced, and thus, the strength of semiconductor packages may be increased.

According to some implementations of the present disclosure, there is provided a method of manufacturing a semiconductor package. The method includes mounting a chip stack structure on a package substrate, the chip stack structure including at least two semiconductor chips each connected to the package substrate via a metal wire, forming a coating layer covering the package substrate, the chip stack structure, and the metal wire through a coating process, and forming a sealing material sealing the chip stack structure on the package substrate.

In an implementation, the forming of the coating layer may be performed using at least one of physical vapor deposition (PVD), chemical vapor deposition (CVD), or atomic layer deposition (ALD).

In an implementation, the forming of the coating layer may include forming a first insulating layer that covers the package substrate, the chip stack structure, and the metal wire, and the first insulating layer may include a short-circuit prevention material.

In an implementation, the forming of the coating layer may include forming a first insulating layer, and forming a second insulating layer including a short-circuit prevention material on the first insulating layer.

In an implementation, the forming of the coating layer may further include forming a barrier layer on the second insulating layer, the barrier layer including a material enhancing adhesion to the sealing material.

In an implementation, the method may further include forming a mask covering a portion of the package substrate prior to the forming the coating layer, and removing the mask prior to the forming of the sealing material.

In an implementation, in the mounting of the chip stack structure, the chip stack structure may be formed by mounting a first semiconductor chip, which is one of the at least two semiconductor chips, on the package substrate, connecting the first semiconductor chip to the package substrate via the metal wire, and then mounting a second semiconductor chip, which is another of the at least two semiconductor chips.

In an implementation, in the mounting of the chip stack structure, the chip stack structure may be formed by stacking all of the at least two semiconductor chips on the package substrate and connecting each of the at least two semiconductor chips to the package substrate via the metal wire.

In an implementation, the chip stack structure may have a stair-step configuration or a zigzag configuration.

In addition, after the forming of the sealing material, the method may further include forming an external connection terminal on a lower surface of the package substrate.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A semiconductor package comprising:
a package substrate;
a chip stack structure on the package substrate and comprising a plurality of semiconductor chips;
a bonding wire connecting each of the plurality of semiconductor chips to the package substrate; and
a sealing material sealing the chip stack structure and the bonding wire on the package substrate,
wherein the bonding wire comprises a metal wire and a coating layer covering the metal wire.

2. The semiconductor package of claim 1, wherein the coating layer comprises a first insulating layer covering the metal wire and a second insulating layer covering the first insulating layer.

3. The semiconductor package of claim 2, wherein the first insulating layer comprises a crosstalk prevention material, and
wherein the second insulating layer comprises a short-circuit prevention material.

4. The semiconductor package of claim 2, wherein the first insulating layer comprises a high-k dielectric material.

5. The semiconductor package of claim 2, wherein the second insulating layer comprises a silicon oxide or a metal oxide.

6. The semiconductor package of claim 2, wherein the coating layer comprises a barrier layer covering the second insulating layer, and
wherein the barrier layer comprises a material configured to adhere to the sealing material.

7. The semiconductor package of claim 1, wherein the coating layer comprises an insulating layer comprising a silicon oxide, a metal oxide, or Parylene.

8. The semiconductor package of claim 1, wherein the coating layer is on an outer surface of the chip stack structure and an outer surface of the package substrate.

9. The semiconductor package of claim 1, wherein the coating layer is on an outer surface of the chip stack structure, a substrate pad on an upper surface of the package substrate, a portion of the upper surface of the package substrate around the substrate pad.

10. The semiconductor package of claim 1, wherein the chip stack structure has a stair-step configuration, a zigzag configuration, or a vertical configuration having aligned lateral surfaces.

11. A semiconductor package comprising:
a package substrate comprising a substrate pad;
a chip stack structure on the package substrate and comprising a plurality of semiconductor chips;
a metal wire connecting a chip pad of each of the plurality of semiconductor chips with the substrate pad;
a coating layer covering the package substrate, the chip stack structure, and the metal wire, and comprising at least one insulating layer; and
a sealing material sealing the chip stack structure and the metal wire on the package substrate.

12. The semiconductor package of claim 11, wherein the coating layer comprises:
a first insulating layer covering the package substrate, the chip stack structure, and the metal wire; and
a second insulating layer covering the first insulating layer,
wherein the first insulating layer comprises a crosstalk prevention material, and
wherein the second insulating layer comprises a short-circuit prevention material.

13. The semiconductor package of claim 12, wherein the coating layer comprises a barrier layer covering the second insulating layer, and
wherein the barrier layer comprises a material configured to adhere to the sealing material.

14. The semiconductor package of claim 11, wherein the coating layer comprises a first insulating layer, and
wherein the first insulating layer comprises a silicon oxide, a metal oxide, or Parylene.

15. The semiconductor package of claim 11, wherein the coating layer covers an outer surface of the chip stack structure and an outer surface of the package substrate, or
wherein the coating layer covers the outer surface of the chip stack structure, the substrate pad, and a portion of an upper surface of the package substrate around the substrate pad.

16. A semiconductor package comprising:
a package substrate;
a chip stack structure on the package substrate and comprising a plurality of semiconductor chips;
a metal wire connecting each of the plurality of semiconductor chips to the package substrate;
a coating layer covering the package substrate, the chip stack structure, and the metal wire, and comprising a first insulating layer and a second insulating layer; and
a sealing material sealing the chip stack structure and the metal wire on the package substrate.

17. The semiconductor package of claim 16, wherein the first insulating layer comprises a high-k dielectric material as a crosstalk prevention material.

18. The semiconductor package of claim 16, wherein the second insulating layer comprises a silicon oxide or a metal oxide as a short-circuit prevention material.

19. The semiconductor package of claim 16, wherein the coating layer comprises a barrier layer covering the second insulating layer, and
wherein the barrier layer comprises a material configured to adhere to the sealing material.

20. The semiconductor package of claim 16, wherein the coating layer covers at least a portion of an exposed surface of the package substrate and an exposed surface of each of the plurality of semiconductor chips, and
wherein the sealing material covers the package substrate, the chip stack structure, and the coating layer on the metal wire.
